(19) United States
(12) Patent Application Publication
(10) Pub. No.: US 2006/0131607 A1
(43) Pub. Date: Jun. 22, 2006

(54) Compound semiconductor device and process for producing the same

(75) Inventors: Hisashi Yamada, Tsukuba (JP); Takenori Osada, Chiba (JP); Noboru Kukuhara, Tsukuba (JP)

Correspondence Address: SUGHRUE MION, PLLC, 2100 PENNSYLVANIA AVENUE, N.W., SUITE 800, WASHINGTON, DC, 20037, US

(73) Assignees: SUMITOMO CHEMICAL COMPANY, LIMITED, Tokyo (JP); SUMIKA EPI SOLUTION COMPANY, LTD, Tokyo (JP)

(21) Appl. No.: 10/546,760

(22) PCT Filed: Feb. 4, 2004
(86) PCT No.: PCT/JP04/01120

§ 371 Date: Aug. 25, 2005

(30) Foreign Application Priority Data
Feb. 25, 2003 (JP) 2003-047223

(51) Int. Cl. H01L 31/109

(52) U.S. Cl. 257/197

(57) ABSTRACT

A compound semiconductor device comprising a hetero junction bipolar transistor including a compound semiconductor substrate, and a sub-collector layer, a collector layer, a base layer and an emitter layer formed in this order as thin crystalline layers on the compound semiconductor substrate by vapor phase deposition, wherein the base layer is a thin film of a p-type compound semiconductor doped with C and no peak of a type of bonding between H and C, C2-H, is detected in infrared absorption measurement at room temperature.

### TECHNICAL FIELD

The present invention relates to a hetero junction bipolar transistor (HBT) element, a compound semiconductor device for HBT, and a process for producing the same.

### BACKGROUND ART

An HBT is a bipolar transistor wherein the emitter-base junction is made a hetero junction by using in an emitter layer a substance having a larger band gap than a base layer, in order to enhance emitter injection efficiency.

For example, a GaAs HBT is generally produced by forming a thin film crystalline wafer of a layer structure wherein a pn junction, which is an emitter-base junction, has the structure of a hetero junction by sequentially growing an n⁺-GaAs layer (sub-collector layer), an n-GaAs layer (collector layer), a p-GaAs layer (base layer), an n-InGaP layer (emitter layer), and an n-GaAs layer (sub-emitter layer) on a semi-insulating GaAs substrate, using a metal organic chemical vapor deposition (MOCVD).

FIG. 7 is a diagram showing the pattern of the layer structure of a conventional commonly used GaAs HBT. In the HBT 100, a sub-collector layer 102 consisting of an n⁺-GaAs layer, a collector layer 103 consisting of an n-GaAs layer, a base layer 104 consisting of a p-GaAs layer, an emitter layer 105 consisting of an n-InGaP layer, a sub-emitter layer 106 consisting of an n⁺-GaAs layer, and an emitter contact layer 107 consisting of an n⁺-InGaAs layer are formed in this order as semiconductor thin crystalline layers on a semi-insulating GaAs substrate 101 using an appropriate vapor phase growing process, such as an MOCVD process. A collector electrode 108 is formed on the sub-collector layer 102, base electrodes 109 are formed on the base layer 104, and an emitter electrode 110 is formed on the emitter contact layer 107.

In thus constituted HBT, the current amplification factor β is represented by the equation:
β=Ic/Ib=(In−Ir)/(Ip+Is+Ir)
where In is an electron injection current from the emitter to the base, Ip is a hole injection current from the base to the emitter, Is is an emitter/base interface recombination current, and Ir is a recombination current in the base.

As the above equation shows, the magnitude of the current amplification factor β is affected by Ir, which is the recombination current in the base, and the recombination current in the base is sensitive to the crystallinity of the base layer. Therefore, in order to obtain good transistor characteristics, the crystallinity in the base layer must be improved.

In the case of fabricating a semiconductor wafer for producing an HBT of a layer structure as shown in FIG. 7, when a p-GaAs thin layer, which becomes the base layer thereof, is grown in a vapor phase by an MOCVD process, carbon (C) contained in a gallium source, trimethyl gallium (TMG) as a p-type dopant, is generally used. For example, it has been known that if the vapor phase deposition is performed at the value of a V/III ratio of about 20 to 150, since the incorporation of C into the thin layer is insufficient, the vapor phase deposition is performed at a V/III ratio of 2.5 or below, wherein the incorporation of C increases sharply (JP-A-3-110829). However, if the thin film crystalline layer of p-GaAs is grown in a vapor phase in an MOCVD reaction furnace, there are caused problems that C used as a dopant bonds with hydrogen (H) contained in the material, much H as 1 to 2×10¹⁹ cm⁻³ is incorporated into the crystal thereof to inactivate the carriers in the base layer, and the current amplification characteristics of the HBT are affected.

Specifically, it is pointed out that if a large quantity of C as a p-type dopant is contained in the base layer in the state of being bonded to H, the initial fluctuation of transistor characteristics referred to as the Ic drift of the current amplification factors β, wherein the current amplification factors are drifted by the collector current during operation as an HBT element, can occur, or problems are caused in long-term reliability.

In order to solve these problems, a process wherein heat treatment is performed after growing the p-GaAs layer, thereby breaking bonds of C and H, and reducing the H concentration in the p-GaAs layer can be considered; however, if this is applied to the above-described well-known process, the trouble of lowered current amplification factor is simultaneously caused.

### DISCLOSURE OF THE INVENTION

The object of the present invention is to provide a compound semiconductor device that can solve the above-described problems in background art, and a process for producing the same.

In order to solve the above-described problems, in the present invention, when a p-GaAs layer to constitute the base layer of an HBT is grown in a vapor phase, the V/III ratio, which is a growing condition is set in the range of 3.3 to 40, and C as a dopant is supplied as a halogenated methane to grow the p-GaAs layer in a vapor phase. A compound semiconductor wafer thus obtained has characteristics in that no or slight peak of C2-H, a type of bonding between H and C, is detected in infrared absorption measurement at room temperature.

Here, the V/III ratio means the quantitative ratio of feed materials for group V and III elements, respectively, to grow a group III-V compound semiconductor crystal. Generally in the metal organic chemical vapor phase epitaxial process, the materials are supplied in the gaseous state from a gas cylinder or a bubbler. The gas supply quantity from the gas cylinder is controlled by a flow rate controller, such as a mass flow controller, installed in the supply line, and (gas concentration in the cylinder)×(gas flow rate) is the actual flow rate of the material. The gas supply quantity from the bubbler is controlled by a flow rate controller, such as a mass flow controller, installed in the carrier gas supply line of the carrier gas flowed to the bubbler, and (carrier gas flow rate)×(vapor pressure of the material in the bubbler)/(internal pressure of the bubbler) is the actual flow rate of the material. The supply quantity ratio of the group V element material and the group III element material in the actual flow rate of the material is generally referred to as the V/III ratio. In this specification also, the term V/III ratio is used as following the above-described definition.

As described above, if a p-GaAs layer is grown wherein the V/III ratio is in the range of 3.3 to 40, and in a vapor phase under the supply of a halogenated methane, the thermal stability of the p-GaAs layer can be favorable. Specifically, if the p-GaAs layer is grown in a vapor phase as described above, even if heat treatment is performed to the p-GaAs layer after vapor-phase growth to break C—H bonds present in the crystal and to reduce the H concentration in the crystal, the lowering of the current amplification factor by this can be suppressed. The V/III ratio is preferably 5 to 35, more preferably 10 to 30, and further preferably 10 to 25.

According to the first aspect of the present invention, there is proposed a compound semiconductor device comprising a hetero junction bipolar transistor comprising a compound semiconductor substrate, and a sub-collector layer, a collector layer, a base layer and an emitter layer formed in this order as thin crystalline layers on the compound semiconductor substrate by vapor phase deposition, wherein the base layer is a thin film of a p-type compound semiconductor doped with C and no peak of C2-H, a type of bonding between H and C, is detected in infrared absorption measurement at room temperature.

According to the second aspect of the present invention, there is proposed the compound semiconductor device in the first aspect, wherein the base layer contains at least one of Ga, Al and In, and contains As as a group V element.

According to a third aspect of the present invention, there is proposed the compound semiconductor device in the first aspect, wherein the vapor phase deposition is of MOCVD.

According to the fourth aspect of the present invention, there is proposed a process for producing a compound semiconductor wafer comprising a hetero junction bipolar transistor structure comprising a compound semiconductor substrate, and a sub-collector layer, a collector layer, a base layer and an emitter layer formed in this order as thin crystalline layers on the compound semiconductor substrate, wherein the base layer is formed by vapor phase deposition of MOCVD by setting a V/III ratio in a range of 3.3 to 40, while supplying a halogenated methane.

According to the fifth aspect of the present invention, there is proposed the process for producing a compound semiconductor wafer in the fourth aspect, wherein the base layer contains at least one of Ga, Al and In, and contains As as a group V element.

According to the sixth aspect of the present invention, there is proposed the process for producing a compound semiconductor wafer in the fourth or fifth aspect, wherein the halogenated methane is CBrCl₃.

According to the seventh aspect of the present invention, there is proposed the process for producing a compound semiconductor wafer in the fourth, fifth or sixth aspect, further including, after growing the base layer, the step of performing heat treatment at a temperature of 600° C. to 700° C. in an atmosphere containing no arsine.

According to the eighth aspect of the present invention, there is proposed a p-type compound semiconductor thin film obtainable by vapor phase deposition of MOCVD so as to contain at least one of Ga, Al and In, contain As as a group V element, and contain C as a dopant, characterized in that no peak of a type of bonding between H and C, C2-H, is detected in infrared absorption measurement at room temperature.

According to the ninth aspect of the present invention, there is proposed a hetero junction bipolar transistor containing a compound semiconductor thin film of the eight aspect as a base layer.

According to the tenth aspect of the present invention, there is proposed a process for verifying quality of a compound semiconductor wafer having a compound semiconductor layer doped with C on a compound semiconductor substrate, which comprises the step of measuring a type of bonding between H and C, C2-H, in the wafer by infrared absorption to verify the quality thereof.

According to the eleventh aspect of the present invention, there is proposed a process for verifying quality of a compound semiconductor wafer having a compound semiconductor layer doped with C on a compound semiconductor substrate, which comprises the steps of producing said wafer by vapor phase deposition, then measuring a type of bonding between H and C, C2-H, in the wafer by infrared absorption to verify the quality thereof.

According to the twelfth aspect of the present invention, there is proposed the process in the tenth or eleventh aspect, wherein the compound semiconductor wafer comprises a hetero junction bipolar transistor structure including the compound semiconductor substrate, and a sub-collector layer, a collector layer, a base layer doped with C and an emitter layer formed in this order on the substrate.

According to the thirteenth aspect of the present invention, there is proposed the process in the tenth, eleventh or twelfth aspect, wherein the compound semiconductor layer doped with C contains at least one of Ga, Al and In, and contains As as a group V element.

### BRIEF DESCRIPTION OF THE DRAWINGS

FIG. 1 is a layer structure diagram showing the pattern of an example of thin film crystalline wafer for HBT produced by the process of the present invention.

FIG. 2 is a diagram the pattern of the major part of the apparatus for producing a vapor-phase grown semiconductor used for producing the semiconductor wafer shown in FIG. 1.

FIG. 3 is a graph showing the measurement results of PL strength in Example 1 and Comparative Example 1.

FIG. 4 is a graph showing the results of infrared absorption for the sample of Example 1 measured at room temperature.

FIG. 5 is a graph showing the results of infrared absorption for the sample of Comparative Example 1 measured at room temperature.

FIG. 6 is a graph showing the Ic drift current dependence of the current amplification factors β in Example 2 and Comparative Example 2.

FIG. 7 is a diagram showing the pattern of the layer structure of a conventional commonly used GaAs HBT.

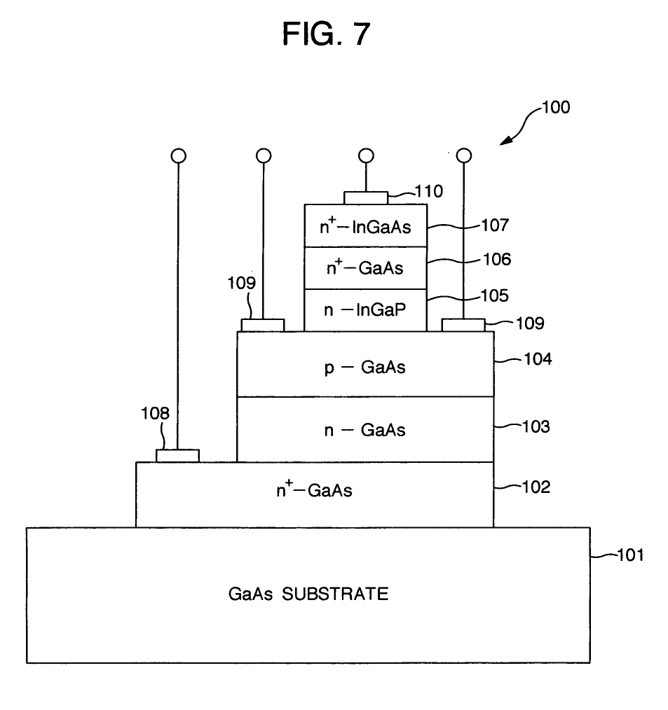

### BEST MODE FOR CARRYING OUT THE INVENTION

An example of the embodiments of the present invention will be described below in detail referring to the drawings.

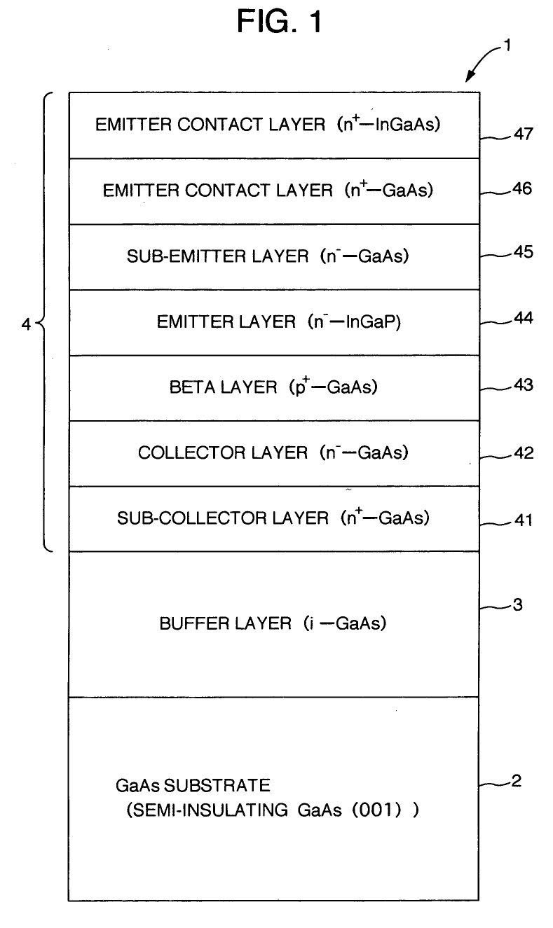

FIG. 1 is a layer structure diagram showing the pattern of an example of thin film crystalline wafer for HBT produced by the process of the present invention. This thin film crystalline wafer is a compound semiconductor wafer used for producing a GaAs HBT. An example of the embodiment when a semiconductor wafer having a layer structure shown in FIG. 1 is produced using a process of the present invention will be described. Therefore, the following description is in no way intended to limit the process of the present invention only to the production of a compound semiconductor wafer having the structure shown in FIG. 1.

The structure of the semiconductor wafer 1 shown in FIG. 1 is as follows: The semiconductor wafer 1 is constituted by sequentially laminating a plurality of thin film semiconductor crystal growing layers on a GaAs substrate 2, which is a semi-insulating GaAs compound semiconductor crystal, using an MOCVD process. The GaAs substrate 2 consists of a semi-insulating GaAs (001) layer, and a buffer layer 3 consisting of an i-GaAs layer is formed on the GaAs substrate 2.

Next, the constitution of an HBT functional layer 4 formed on the buffer layer 3 will be described. In the HBT functional layer 4, an n⁺-GaAs layer operating as a sub-collector layer 41 and an n⁻-GaAs layer operating as a collector layer 42 are sequentially formed on the buffer layer 3 as epitaxially grown semiconductor crystalline layers in a predetermined thickness. Then, a p⁺-GaAs layer operating as a base layer 43 is formed on the collector layer 42 similarly as an epitaxially grown semiconductor crystalline layer, and an n-InGaP layer operating as an emitter layer 44 is formed on the base layer 43. Then, on the emitter layer 44, an n⁻-GaAs layer is formed as a sub-emitter layer 45, and an n⁺-GaAs layer and an n⁺-InGaAs layer are formed as emitter contact layers 46 and 47, respectively.

Here, the base layer 43 is formed as a thin film compound semiconductor layer that contains at least one of Ga, Al and In, contains As as a group V element, and contains carbon (C) as a material of a p-type dopant. As the material of a p-type dopant, for example, a halogenated methane described below is normally used.

A process for forming the above-described each layer as a thin layer of a epitaxially grown semiconductor crystal using MOCVD will be described in detail.

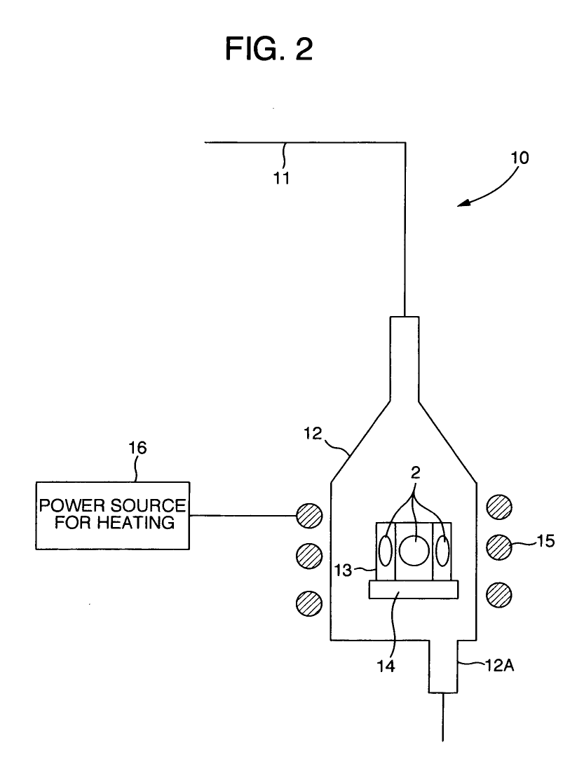

FIG. 2 schematically shows the major part of a vapor-phase grown semiconductor production unit 10 used for producing a semiconductor wafer 1 shown in FIG. 1 using MOCVD. The vapor-phase grown semiconductor production unit 10 is equipped with a reactor 12 to which a material gas is supplied from a material supply system (not shown) through a material supply line 11, and a susceptor 13 for holding and heating a GaAs substrate 2 is installed in the reactor 12.

In this embodiment, the susceptor 13 is a polygonal prismatic body, and a plurality of GaAs substrates 2 are held on the surface. The susceptor 13 has a well known structure wherein the susceptor 13 can be rotated by a rotating device 14. What is denoted by the reference numeral 15 is a coil for heating the susceptor 13 by high-frequency induction. By allowing a current for heating to flow from a heating power source 16 to the coil 15, the GaAs substrate 2 can be heated to a required growing temperature. By this heating, the material gas supplied in the buffer layer 3 through the material supply line 11 is thermally decomposed on the GaAs substrate 2, and a desired semiconductor thin film crystal can be grown in a vapor phase on the GaAs substrate 2. The used gas is discharged outwardly from an exhaust port 12A, and transferred to exhaust gas treatment equipment.

After placing the GaAs substrate 2 on the susceptor 13 in the reactor 12, hydrogen is used as a carrier gas, arsine and trimethyl gallium (TMG) are used as materials, and GaAs is grown by about 500 nm at 650° C. as the buffer layer 3. Thereafter, the sub-collector layer 41 and the collector layer 42 are grown on the buffer layer 3 under the condition of a growing temperature of 620° C.

Then, on the collector layer 42, the base layer 43 is grown using trimethyl gallium (TMG) as feed material for a group-III material, arsine (AsH₃) as feed material for a group-V element, and CBrCl₃ as feed material for a p-type forming dopant, at a growing temperature of 620° C. When the base layer 43 is grown, the carrier concentration in the base layer 43 can be adjusted by controlling the flow rate of the CBrCl₃. To adjust the carrier concentration, other halogenated methane can also be used.

Here, in order to make heat stability of the base layer 43 favorable, the V/III ratio in the growth conditions when the base layer 43 is grown in a vapor phase using MOCVD is adjusted in the range of 3.3 to 40.

The reason is as follows: there are two types of bonding between C and H in a p-GaAs layer, C—H and C2-H. If the p-GaAs layer is grown in a range of the V/III ratio of 3.3 to 40, C—H bonds will be dominant, which makes the bonding of C with H easily broken by heat treatment after its growth, resulting in an excellent heat stability. On the other hand, if the V/III ratio is less than 3.3, the bonding aspect of C2-H increases compared with the bonding aspect of C—H, and two types of bonds, C—H bonds and C2-H bonds, exist in the crystal of the formed base layer 43. As a result, even if heat treatment is performed after the p-GaAs layer has been grown as the base layer 43, the C2-H bonds are not easily broken, resulting in the inhibition of heat stability.

After thus growing the base layer 43, an emitter layer 44 and a sub-emitter layer 45 are grown at a growing temperature of 620° C. on the base layer 43, and emitter contact layers 46 and 47 are formed on the sub-emitter layer 45.

In the semiconductor wafer 1, since the base layer 43 that constitutes an HBT is obtained by vapor phase deposition of MOCVD by adjusting the V/III ratio in a range of 3.3 to 40, and supplying a halogenated methane, as described above, the heat stability of the base layer 43 is extremely high. Therefore, if heat treatment is performed as described below, the C—H bonds can be easily broken, the H concentration in the base layer 43 is lowered, and thereby, the Ic drift dependence of the current amplification factor β of the HBT can be reduced compared with conventional HBTs without lowering the current amplification factor β of the HBT. The resulting HBT should be well stabilized.

Although TMG (Ga) was used as the material of the group III element in the above-described embodiment, other materials, such as Al and In, can also be used. Although Ga, Al or In may be used lone, more than one of these can also be used in combination. As the material for the group V element, other than As, a suitable material for the group V element containing As can be used to grow the base layer 43.

Since CBrCl₃ is used as the material of the dopant, and carbon (C) is doped to make the base layer 43 p-type, by adequately adjusting the flow rate of CBrCl₃ when the base layer 43 is grown to adjust the doping quantity of carbon (C), and thereby the carrier concentration in the base layer 43 can be controlled independently from the growing conditions.

Since the quantity of C contained in TMG incorporated in the crystal is generally reduced if the V/III ratio is raised when the base layer 43 is grown, the carrier concentration is lowered. Therefore, a C dopant must be supplied from an external source; however, if a CBrCl₃ material is used, the carrier concentration of about 4×10¹⁹ cm⁻³ can be sufficiently controlled because of a high vapor pressure.

Besides the flow rate control of CBrCl₃, the carrier concentration in the base layer 43 can be similarly controlled by flowing a halogenated methane during growing, and controlling the flow rate thereof. As the halogenated methane other than the above described, for example, CBr₄, CBr₃Cl, CBr₂Cl₂, CCl₄ or the like can be used.

As described above, if the semiconductor wafer 1 as shown in FIG. 1 is produced, and an HBT is produced using the semiconductor wafer 1, the heat stability of the base layer 43 is improved. Therefore, after growing the base layer 43, even if a treatment for easily breaking the bonds of C and H by heat-treating the base layer 43 at a temperature between 600° C. and 700° C., for reducing the H concentration in the base layer 43 is performed, the current amplification factor is not thereby lowered. As a result, the Ic drift characteristics of the current amplification factor β can be significantly improved without lowering the current amplification factor. This heat treatment is preferably performed in an atmosphere not containing arsine.

### EXAMPLE 1

A semiconductor thin film of a structure wherein a p-GaAs layer of a thickness of 1 μm was sandwiched with AlGaAs layers was fabricated. The p-GaAs layer was grown on the AlGaAs layers by vapor phase growing by an MOCVD process under the growing condition of a V/III ratio of 25, using trimethyl gallium (TMG) as the material of the group III element, using arsine (AsH₃) as the material of the group V element, and using CBrCl₃ as the p-type dopant, at a growing temperature of 620° C. After growing, thus fabricated sample was subjected to heat treatment at 500° C. to 670° C. for 5 minutes, and the photoluminescence intensity (PL intensity) of the sample was measured at room temperature.

### COMPARATIVE EXAMPLE 1

As Comparative Example 1, a sample was fabricated under the same conditions as in Example 1 except that the p-GaAs layer was grown under the growing condition of a V/III ratio of 0.7, and after growing, the sample for comparison was subjected to annealing treatment at 500° C., 550° C., 600° C., 650° C. or 670° C. For thus obtained sample for comparison, the PL intensity was also measured.

These measurement results are as follows: Example 1

(V/III ratio = 25)

| Annealing temperature (° C.) | PL strength (A.U.) |
|---|---|
| As grown | 100 |
| 550° C. | 107 |
| 600° C. | 112 |
| 650° C. | 102 |
| 670° C. | 89 |

### COMPARATIVE EXAMPLE 1

(V/III ratio = 0.7)

| Annealing temperature (° C.) | PL strength (A.U.) |
|---|---|
| As grown | 100 |
| 500° C. | 102 |
| 550° C. | 98 |
| 600° C. | 46 |
| 650° C. | 15 |
| 670° C. | 9 |

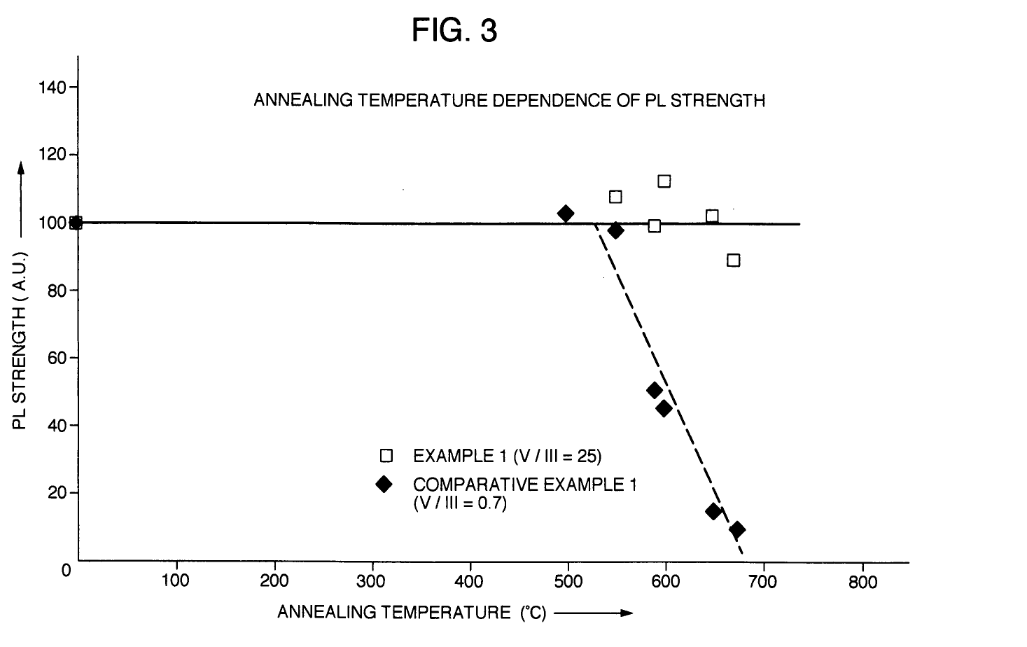

FIG. 3 shows the graph of these measurement results. When the cases wherein the V/III ratio is 25 and 0.7 are compared, in the case of the V/III ratio of 25, it is seen that the PL intensity does not change and crystallinity is not deteriorated even after heat treatment, that is, heat stability is favorable. In the case of the V/III ratio of 0.7, it is seen that the PL intensity lowers after heat treatment at 600° C. or above, and crystallinity is deteriorated.

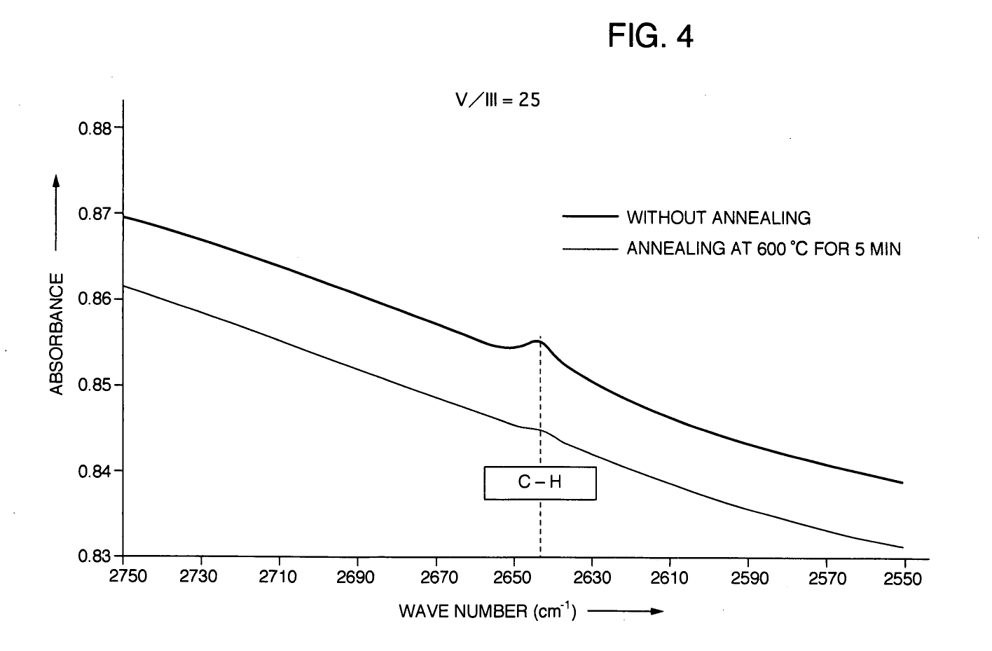

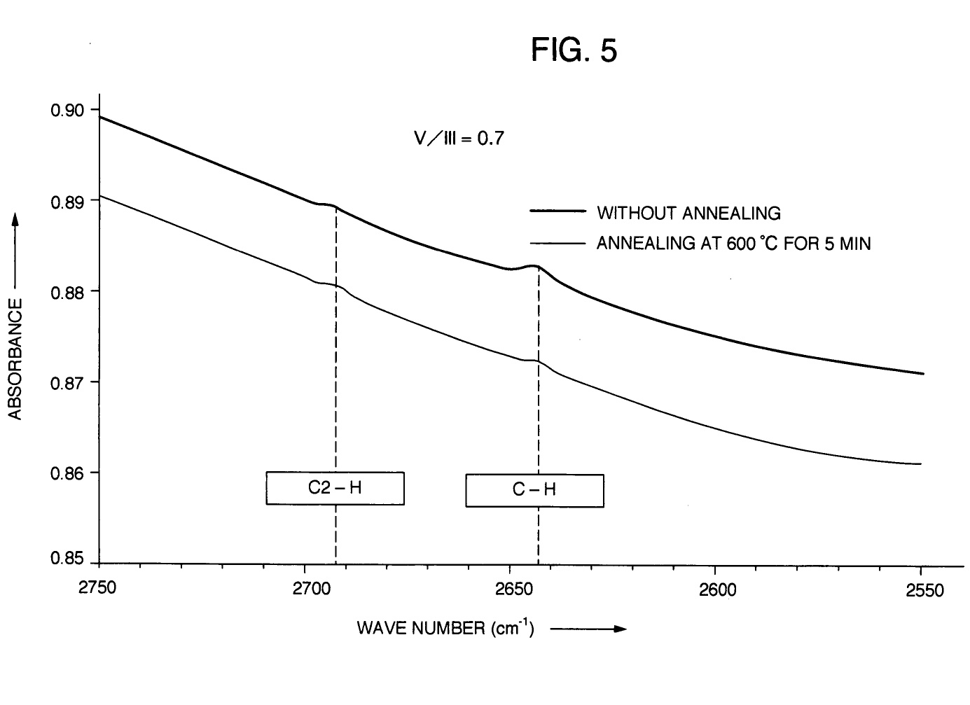

For the samples of the above-described Example 1 and Comparative Example 1, the measurements of infrared absorption were performed at room temperature. These measurements were performed for as-grown samples and the samples after heat treatment at 600° C. for 5 minutes. The results of these measurements are shown in FIGS. 4 and 5, respectively. The followings are seen from these results of measurements:

Regarding as-grown samples, when attention is focused on the bonding of C and H, only C—H bonds are detected in the case of the V/III ratio of 25, and no C2-H bonds are detected. On the other hand, in the case of the V/III ratio of 0.7, in addition to C—H bonds, C2-H bonds were also observed.

When each sample is subjected to heat treatment at 600° C. for 5 minutes, the peak intensity caused by the C—H bond is reduced in either case of V/III ratio of 25 or 0.7; however, when the V/III ratio is 0.7, the peak intensity of the C2-H bond is not reduced even by the above-described heat treatment. It was found from this that the C2-H bond was difficult to break even by heat treatment. From the above facts, it can be said that H is easily left in the crystal when the V/III ratio is 0.7, even if the as-grown sample is subjected to heat treatment, and therefore, the heat stability of the p-GaAs layer grown when the V/III ratio is 25 is superior to the case wherein the V/III ratio is 0.7.

### EXAMPLE 2

A compound semiconductor wafer having a layer structure as shown in FIG. 1 was fabricated under the conditions described for the embodiment, and using thereby obtained semiconductor wafer, an HBT element was fabricated as follows: The emitter size was 100 μm×100 μm. Here, the collector current/the base current when 1 kA/cm² of the collector current is flowed is referred to as the current amplification factor β. The base layer 43 was grown in a vapor phase by MOCVD at the V/III ratio of 25, and then subjected to heat treatment at 670° C. for 0 to 10 minutes.

For thus fabricated HBT, measurement for finding out the relationship between Ic drift (%) and current amplification factor β was performed.

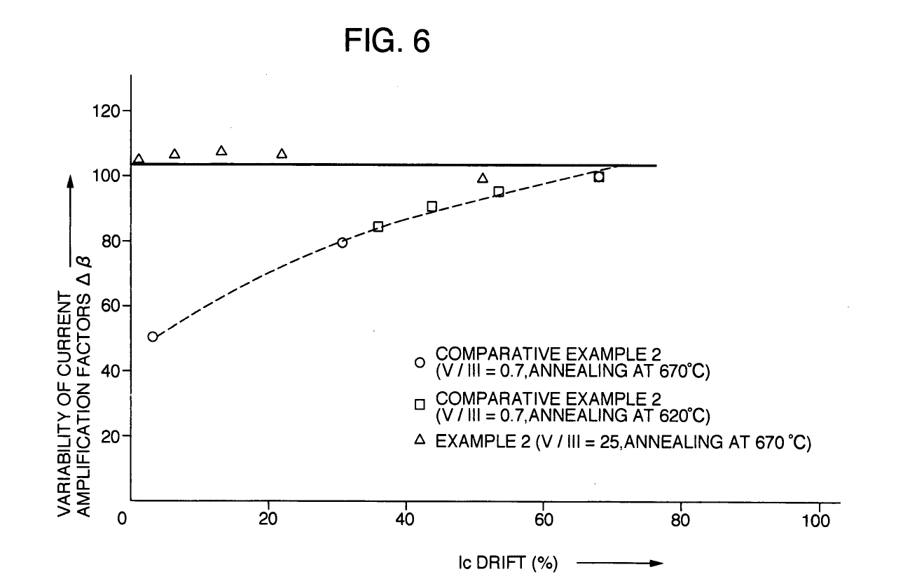

FIG. 6 shows a graph of the measurement results. FIG. 6 shows the Ic drift current dependence of the coefficient of fluctuation Δβ of the current amplification factor β. The Δβ is standardized by β without annealing, and the Ic drift current is defined by the equation, Ic drift=(Icf−Ici)/Ic×100 (Ici: initial value of collector current, Icf: saturated value of collector current). These characteristics have been known to have correlation with the H quantity in the base layer, and on device operation, the Ic drift current of 10% or less is desired. It is seen from the graph shown in FIG. 6 that the Ic drift current dependence of the current amplification factor β is extremely small in Example 2 fabricated at the V/III ratio of 25.

### COMPARATIVE EXAMPLE 2

The fabrication and measurement of an HBT were performed in the same manner as in Example 2, except that the base layer was formed under the growing condition of a V/III ratio of 0.7. In Comparative Example 2, heat treatment was performed at 670° C. and 620° C.

The measurement results are shown as a graph in FIG. 6. It is seen from FIG. 6 that the Ic drift current dependence of the current amplification factor β is extremely large, and is lowered as much as 50% in Comparative Example 2 (V/III ratio=0.7), and that the transistor characteristics of Example 2 are extremely excellent.

### INDUSTRIAL APPLICABILITY

According to the present invention, a p-type compound semiconductor thin film using C as a dopant can be made thermally stable by suppressing the formation of C2-H in the bonding structure of C and H. As a result, the quantity of H in the crystal can be easily decreased by heat treatment. Therefore, by using the p-type compound semiconductor thin film as a base layer of an HBT, the Ic drift current dependence of the current amplification factor β can be made smaller while maintaining the current amplification factor, and a high-performance HBT element can be realized. Furthermore, when a compound semiconductor wafer having an HBT structure is fabricated, since a compound semiconductor wafer suitable for fabricating a high-performance HBT can be easily produced by making the V/III ratio, which is one of growing conditions, within the required range, in the step of growing a compound semiconductor thin layer to become a base layer, a high-performance HBT element can be realized in low costs.

1. A compound semiconductor device comprising a hetero junction bipolar transistor comprising a compound semiconductor substrate, and a sub-collector layer, a collector layer, a base layer and an emitter layer formed in this order as thin crystalline layers on said compound semiconductor substrate by vapor phase deposition,
wherein said base layer is a thin film of a p-type compound semiconductor doped with C and no peak of a type of bonding between H and C, C2-H, is detected in infrared absorption measurement at room temperature.

2. The compound semiconductor device according to claim 1, wherein said base layer contains at least one of Ga, Al and In, and contains As as a group V element.

3. The compound semiconductor device according to claim 1, wherein said vapor phase deposition is of a metal organic chemical vapor deposition (MOCVD).

4. A process for producing a compound semiconductor wafer comprising a hetero junction bipolar transistor structure comprising a compound semiconductor substrate, and a sub-collector layer, a collector layer, a base layer and an emitter layer formed in this order as thin crystalline layers on said compound semiconductor substrate, wherein said base layer is formed by vapor phase deposition of MOCVD by setting a V/III ratio in a range of 3.3 to 40, while supplying a halogenated methane.

5. The process according to claim 4, wherein said base layer contains at least one of Ga, Al and In, and contains As as a group V element.

6. The process according to claim 4 or 5, wherein said halogenated methane is CBrCl₃.

7. The process according to claim 4 or 5, further including, after growing said base layer, the step of performing heat treatment at a temperature of 600° C. to 700° C. in an atmosphere containing no arsine.

8. A p-type compound semiconductor thin film obtainable by vapor phase deposition of MOCVD so as to contain at least one of Ga, Al and In, contain As as a group V element, and contain C as a dopant, characterized in that no peak of a type of bonding between H and C, C2-H, is detected in infrared absorption measurement at room temperature.

9. A hetero junction bipolar transistor containing a compound semiconductor thin film of claim 8 as a base layer.

10. A process for verifying quality of a compound semiconductor wafer having a compound semiconductor layer doped with C on a compound semiconductor substrate, which comprises the steps of measuring a type of bonding between H and C, C2-H, in said wafer by infrared absorption to verify the quality thereof.

11. A process for verifying quality of a compound semiconductor wafer having a compound semiconductor layer doped with C on a compound semiconductor substrate, which comprises the steps of producing said wafer by vapor phase deposition, then measuring a type of bonding between H and C, C2-H, in said wafer by infrared absorption to verify the quality thereof.

12. The process according to claim 10 or 11, wherein said compound semiconductor wafer comprises a hetero junction bipolar transistor structure including said compound semiconductor substrate, and a sub-collector layer, a collector layer, a base layer doped with C and an emitter layer formed in this order on said substrate.

13. The process according to claim 10 or 11, wherein said compound semiconductor layer doped with C contains at least one of Ga, Al and In, and contains As as a group V element.

14. The process according to claim 6, further including, after growing said base layer, the step of performing heat treatment at a temperature of 600° C. to 700° C. in an atmosphere containing no arsine.

15. The process according to claim 12, wherein said compound semiconductor layer doped with C contains at least one of Ga, Al and In, and contains As as a group V element.
